(19) United States
(12) Patent Application Publication
(10) Pub. No.: US 2021/0302503 A1
(43) Pub. Date: Sep. 30, 2021

(54) COMPUTER-READABLE RECORDING MEDIUM HAVING STORED THEREIN ABNORMALITY DETECTION PROGRAM, ABNORMALITY DETECTION METHOD, AND ABNORMALITY DETECTION APPARATUS

(71) Applicant: FUJITSU LIMITED, Kawasaki-shi (JP)

(72) Inventor: Toshio ITO, Kawasaki (JP)

(73) Assignee: FUJITSU LIMITED, Kawasaki-shi (JP)

(21) Appl. No.: 17/210,500

(22) Filed: Mar. 24, 2021

(30) Foreign Application Priority Data
Mar. 31, 2020 (JP) 2020-064591

(51) Int. Cl. G01R 31/367; G06F 17/18; G01R 31/385; G01R 31/00

(52) U.S. Cl. CPC G01R 31/367; G01R 31/007; G01R 31/385; G06F 17/18

(57) ABSTRACT

An abnormality detection method is performed by a computer. The method includes: executing, for combinations of a plurality of items selected from measurement items related to a moving object, first determination of whether or not a relationship between measurement values of the plurality of items has a linearity by using a portion of the measurement values of the plurality of items; executing, by using the measurement values of the plurality of items when an abnormality occurs, second determination of whether or not the relationship between the measurement values of the plurality of items when the abnormality occurs has the linearity; and selecting the combinations of the plurality of items as monitoring target items for detecting an abnormality of the moving object when the relationship has the linearity in a normal state and the relationship does not have the linearity in an abnormal state.

### CROSS-REFERENCE TO RELATED APPLICATION

This application is based upon and claims the benefit of priority of the prior Japanese Patent Application No. 2020-064591, filed on Mar. 31, 2020, the entire contents of which are incorporated herein by reference.

### FIELD

The embodiments discussed herein are related to a computer-readable recording medium having stored therein an abnormality detection program and the like.

### BACKGROUND

Electric vehicles (EV) that travel by power of a battery are becoming widespread. When a battery of the EV fails during traveling, the EV may stop on a road without continuing traveling. Thus, it is desirable to detect an abnormality of the battery at an early stage before the battery fails. When an abnormality of the battery may be detected at an early stage, the battery may be replaced at a repair shop before the battery fails.

For example, as a technique for detecting an abnormality of a battery, there is a technique of the related art for determining a state of the battery based on a current of the battery and a voltage when the battery is divided into a plurality of blocks. Japanese Laid-open Patent Publication No. 2011-145105 is an example of related art.

### SUMMARY

According to an aspect of the embodiments, an abnormality detection method performed by a computer, the method including: executing, for combinations of a plurality of items selected from measurement items related to a moving object, first determination of whether or not a relationship between measurement values of the plurality of items has a linearity by using a portion of the measurement values of the plurality of items; executing, by using the measurement values of the plurality of items when an abnormality occurs, second determination of whether or not the relationship between the measurement values of the plurality of items when the abnormality occurs has the linearity; and selecting the combinations of the plurality of items as monitoring target items for detecting an abnormality of the moving object when the relationship has the linearity in a normal state and the relationship does not have the linearity in an abnormal state.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a relationship between a voltage and a current of a battery;

FIG. 2 is a diagram for explaining an abnormality due to a deposit to a coupling portion;

FIG. 3 is a functional block diagram illustrating a configuration of an abnormality detection apparatus according to the present embodiment;

FIG. 4 is a diagram illustrating an example of a data structure of a monitoring target item table;

FIG. 5 is a functional block diagram illustrating a configuration of an evaluation device according to the present embodiment;

FIG. 6 is a flowchart illustrating a processing procedure of an abnormality detection apparatus according to the present embodiment;

FIG. 7 is a flowchart illustrating a processing procedure of an evaluation device according to the present embodiment;

FIG. 8 is a diagram illustrating an example of a hardware configuration of a computer that implements functions similar to those of an abnormality detection apparatus according to an embodiment; and

FIG. 9 is a diagram illustrating an example of a hardware configuration of a computer that implements functions similar to those of an evaluation device according to an embodiment.

### DESCRIPTION OF EMBODIMENTS

Since an abnormality of a battery is not detected only by measurement values of a current, a voltage, and the like, it is preferable to detect an abnormality of a battery by combining measurement values of various items.

However, in a case where combinations of items are specified from all items of data obtained from an EV, and whether or not all of the specified combinations of items are useful combinations for detecting an abnormality of a battery is calculated, an amount of calculation increases.

According to an aspect, an object of the embodiment is to provide an abnormality detection program, an abnormality detection method, and an abnormality detection apparatus capable of suppressing an increase in an amount of calculation for selecting a combination of items for performing abnormality detection.

Hereinafter, embodiments of an abnormality detection program, an abnormality detection method, and an abnormality detection apparatus disclosed in the present application will be described in detail with reference to the drawings. The present disclosure is not limited to the embodiments.

### Embodiments

Before describing an abnormality detection apparatus according to the present embodiment, a reference technique will be described. An apparatus that implements the reference technique is referred to as a “reference apparatus” for convenience. The reference apparatus acquires data in a normal state and data in an abnormal state from an EV and executes processing at the time of learning described below to specify a “monitoring target item”. The monitoring target item indicates a combination of a plurality of items, and a relationship between the plurality of items is linear in the normal state, but the linearity collapses in the abnormal state. The reference apparatus executes processing at the time of evaluation by using the monitoring target item, and detects an abnormality of an EV to be evaluated.

The processing at the time of learning by the reference apparatus will be described. Data in a normal state is referred to as data D and defined by Equation (1). As represented by Equation (1), a plurality of measurement values dᵢ are arranged in time series in data D (where, i=1, 2, 3, . . . , n). n is the number of measurement values.

D={d₁,d₂, . . . ,dₙ} (1)

A measurement value dᵢ at a certain time included in the data D is defined by Equation (2). As represented by Equation (2), the measurement value dᵢ includes measurement values d_{i,1}, . . . , d_{i,m}^{˜} of a plurality of items at a certain time. “m^{˜}” described in the specification corresponds to a symbol represented by “a” in Equation (2). m^{˜} is the number of items.

$$\begin{matrix}{d}_{i} = ( {d}_{i , 1} , {d}_{i , 2} , … , {d}_{i , \tilde{m}} ) \\ {↑}_{a}\end{matrix} \qquad ( 2 )$$

Data in the abnormal state is referred to as data D′ and defined by Equation (3). As represented by Equation (3), a plurality of measurement values d′ᵢ are arranged in time series in data D′ (where, i=1, 2, 3, . . . , n′). n′ is the number of measurement values.

$${D}^{′} = \{ {d}_{1}^{′} , {d}_{2}^{′} , … , {d}_{{n}^{′}}^{′} \} \qquad ( 3 )$$

A measurement value d′ᵢ at a certain time included in data D′ is defined by Equation (4). As represented by Equation (4), the measurement value d′ᵢ includes measurement values d′_{i,1}, . . . , d′_{i,m}^{˜} of a plurality of items at a certain time. m^{˜} is the number of items.

$${d}_{i}^{′} = ( {d}_{i , 1}^{′} , {d}_{i , 2}^{′} , … , {d}_{i , \tilde{m}}^{′} ) \qquad ( 4 )$$

For example, the plurality of items included in the measurement value dᵢ represented by Equation (2) and the measurement value d′ᵢ represented by Equation (4) include items related to traveling of an EV such as a voltage, a current, an odometer, and the number of revolutions per minute of an engine. When a plurality of batteries are mounted on the same EV and the same control is performed on the plurality of batteries, the plurality of items may include a voltage, a current, and the like of the batteries.

The reference apparatus selects a plurality of items (1≤j₁, <, . . . <, jₘ≤m^{˜}) from all the items. The reference apparatus determines that the plurality of selected items have a linear relationship with each other in a normal state and the original linearity of each other is largely collapsed in an abnormal state, by the following processing. The reference apparatus adopts the plurality of selected items as “monitoring target items” when the following is satisfied.

The reference apparatus creates a linear regression model for the measurement values of the plurality of selected items for data D in a normal state, and determines whether or not an error between the measurement values and the linear regression model is small.

The reference apparatus creates, from the data D, sub-data Dₘ obtained by narrowing down the items to j₁, . . . , jₘ. The items “j₁, . . . , jₘ” correspond to the plurality of selected items. The sub-data Dₘ is represented by Equation (5). A measurement value d_{m,i} at a certain time included in the sub-data Dₘ is defined by Equation (6). As represented by Equation (6), the measurement value d_{m,i} includes measurement values d_{i,j1}, . . . , d_{i,jm} of a plurality of items at a certain time.

$$\begin{matrix}{D}_{m} = \{ {d}_{m , 1} , {d}_{m , 2} , … , {d}_{m , n} \} & ( 5 ) \\ {d}_{m , i} = ( {d}_{i , {j}_{1}} , {d}_{i , {j}_{2}} , … , {d}_{i , {j}_{m}} ) & ( 6 )\end{matrix}$$

The reference apparatus creates a linear regression model from the sub-data Dₘ by a least squares method. The linear regression model is represented by Equation (7). β₀, β₁, . . . , βₘ₋₁ included in Equation (7) are coefficients of a linear regression model calculated by a least squares method.

y==f(x₁+x₂, . . . ,xₘ₋₁)=β₀+β₁x₁+ . . . +βₘ₋₁xₘ₋₁ (7)

A manager of the reference apparatus sets δδ₁>0 as a threshold in advance. When the condition represented by Equation (8) is satisfied, the reference apparatus determines that the plurality of selected items have a linearity relationship, and executes evaluation using data D′ in the abnormal state. In the following description, the plurality of selected items satisfying the condition represented by Equation (8) are referred to as “monitoring target candidate items”.

On the other hand, in a case where the condition represented by Equation (8) is not satisfied, the reference apparatus determines that there is no linearity relationship between the plurality of selected items, and ends the processing (selects a plurality of items in different combinations again, executes the above-described processing, and determines whether or not the condition represented by Equation (8) is satisfied).

$$ɛ = {max}_{i = 1 , … , n} \vert {β}_{0} + {β}_{1} {d}_{i , {j}_{1}} + … + {β}_{m - 1} {d}_{i , {j}_{m - 1}} \vert < {δ}_{1} \qquad ( 8 )$$

Subsequently, when the condition represented by Equation (8) is satisfied, the reference apparatus determines whether or not there is a large error between the measurement values of the monitoring target candidate items and the linear regression model for the data D′ in the abnormal state. The reference apparatus creates sub-data D′m obtained by narrowing down the items to j₁, . . . , jₘ from the data D′. The items j₁, . . . , jₘ correspond to the monitoring target candidate items. The sub-data D′m is represented by Equation (9). A measurement value d′_{m,i} at a certain time included in the sub-data D′ₘ is defined by Equation (10). As represented by Equation (10), the measurement value d′_{m,i} includes measurement values d′_{i,j1}, . . . , d′_{i,jm} of a plurality of items at a certain time.

$$\begin{matrix}{D}_{m}^{′} = \{ {d}_{m , 1}^{′} , {d}_{m , 2}^{′} , … , {d}_{m , n}^{′} \} & ( 9 ) \\ {d}_{m , i}^{′} = ( {d}_{i , {j}_{1}}^{′} , {d}_{i , {j}_{2}}^{′} , … , {d}_{i , {j}_{m}}^{′} ) & ( 10 )\end{matrix}$$

A manager of the reference apparatus sets δ₂>1 as a threshold in advance. The reference apparatus determines that the linearity of the monitoring target candidate items collapses when the condition represented by Equation (11) is satisfied, and adopts the monitoring target candidate items as “monitoring target items”. “ε” included in Equation (11) corresponds to “ε” in Equation (8). On the other hand, when Equation (11) is not satisfied, the reference apparatus does not adopt the monitoring target candidate items as the monitoring target items.

$${max}_{i = 1 , … , n} \vert {β}_{0} + {β}_{1} {d}_{i , {j}_{1}}^{′} + … + {β}_{m - 1} {d}_{i , {j}_{m - 1}}^{′} - {d}_{i , {j}_{m}}^{′} \vert > {δ}_{2} ɛ \qquad ( 11 )$$

As described above, in the processing at the time of learning by the reference apparatus, a plurality of items are selected from all the items, and when the plurality of selected items satisfy the condition of Equation (8) and the condition of Equation (11), the plurality of selected items are adopted as monitoring target items. The relationship between the measurement values of the monitoring target items is linear in a normal state, but the linearity collapses in an abnormal state. The reference apparatus repeatedly executes the above-described processing for all the combinations while changing the combinations of the plurality of items selected from all the items. For example, the reference apparatus performs determination for a plurality of monitoring target items.

Next, processing at the time of evaluation in which the reference apparatus detects an abnormality of the EV by using the monitoring target items will be described. The reference apparatus acquires data to be evaluated from the EV. Data d to be evaluated is represented by Equation (12).

$$d = ( {d}_{1} , {d}_{2} , … , {d}_{\tilde{m}} ) \qquad ( 12 )$$

The reference apparatus determines that the linearity largely collapses in a case where the data d to be evaluated satisfies the condition represented by Equation (13), and detects an abnormality. β₀, β₁, . . . , βₘ₋₁ in Equation (13) are coefficients of the linear regression model calculated at the time of learning. δ₂ is a threshold set at the time of learning. “ε” included in Equation (13) corresponds to “E” in Equation (8).

|β₀+β₁dⱼ_{₁}+ . . . +βₘ₋₁dⱼ_{_{m−1}}−dⱼ_{ₘ}|>δ₂ε (13)

The reference apparatus acquires data d to be evaluated from the EV at predetermined time intervals, and repeatedly executes the above-described processing.

In a case where the reference apparatus creates a linear regression model by a least squares method, the reference apparatus solves a normal equation represented by Equation (14).

$${\tilde{D}}_{m}^{T} {\tilde{D}}_{m} β = {{\tilde{D}}_{m}^{T}}_{{↑}_{b}} y \qquad ( 14 )$$

In Equation (14), D^{˜}ₘ is defined by Equation (15). “D^{˜}ₘ” described in the specification corresponds to a symbol represented by “b” in Equation (14). y is defined by Equation (16). β is defined by Equation (17).

$$\begin{matrix}{\tilde{D}}_{m} = ( \begin{matrix}1 & {d}_{1 , {j}_{1}} & … & {d}_{1 , {j}_{m - 1}} \\ ⋮ & ⋮ & ⋱ & ⋮ \\ 1 & {d}_{n , {j}_{1}} & … & {d}_{n , {j}_{m - 1}}\end{matrix} ) & ( 15 ) \\ y = ( \begin{matrix}{d}_{1 , {j}_{m}} \\ ⋮ \\ {d}_{n , {j}_{m}}\end{matrix} ) & ( 16 ) \\ β = ( \begin{matrix}{β}_{0} \\ ⋮ \\ {β}_{m - 1}\end{matrix} ) & ( 17 )\end{matrix}$$

In Equation (14), the amount of calculation of D^{˜}ₘ^{T}D^{˜}ₘ is o (nm²). The amount of calculation of D^{˜}ₘ^{T}y is o (nm). The inverse matrix calculation of D^{˜}ₘ^{T}D^{˜}ₘ is o (m²). For example, the total amount of calculation for solving Equation (14) is o (nm²)+o (nm)+o (m²), and the amount of calculation increases as n or m increases. For example, when n=10000, and m=5, the amount of calculation is “300025”.

There are many combinations that may be obtained by selecting a plurality of items from all the items. Therefore, creating a linear regression model by a least squares method for the items in all the combinations in the processing of the reference technique is problematic because the amount of calculation increases. The amount of calculation for creating linear regression models for all combinations of items is defined by Equation (18). For example, the amount of calculation when m^{˜}=10, and n=10000 is 3.3×10⁷.

$${\sum }_{m = 2}^{\tilde{m}} = ( \begin{matrix}\tilde{m} \\ m\end{matrix} ) ( o ( n {m}^{2} ) + o ( n m ) + o ( {m}^{2} ) ) \qquad ( 18 )$$

Next, a physical characteristic of the EV will be described. As for the physical characteristic of the EV, there is physical characteristics having a linearity relationship with each other in a normal state, the original linearity of each other being largely collapsed in an abnormal state.

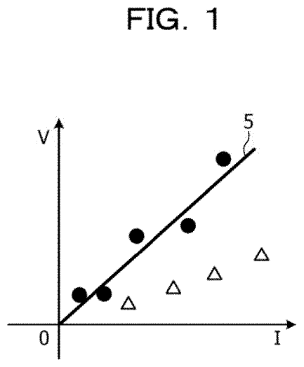

For example, a voltage and a current of a battery have a linearity relationship, and widely various voltage values and current values are observed. FIG. 1 is a diagram illustrating a relationship between a voltage and a current of a battery. A horizontal axis in FIG. 1 is an axis corresponding to a measurement value of a current. A vertical axis in FIG. 1 is an axis corresponding to a measurement value of a voltage. Each of circles illustrated in FIG. 1 corresponds to data in a normal state. Each of triangles corresponds to data in an abnormal state.

The linear regression model based on the data in the normal state is indicated by a line segment 5. The measurement values of the voltage and the current have less noise, and a square error with the linear regression model becomes small. For example, even when some measurement values are randomly picked up instead of using all the measurement values of the voltage and the current, a bias of the measurement values becomes small.

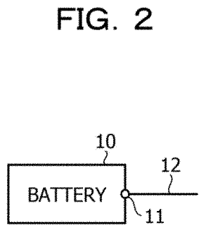

FIG. 2 is a diagram for explaining an abnormality due to a deposit to a coupling portion. In FIG. 2, a wiring 12 is coupled to a battery 10 of the EV via a coupling portion 11. When the coupling portion 11 is deteriorated and a deposit is attached, a resistance of the coupling portion 11 changes, and the original linearity largely collapses. For example, the data in the normal state illustrated in FIG. 1 becomes the data in the abnormal state.

Next, processing of the abnormality detection apparatus according to the present embodiment will be described. As illustrated by using the physical characteristics of the EV with reference to FIG. 1, even when some measurement values are randomly picked up instead of using all the measurement values of each item, the measurement values are less likely to be biased. For this reason, in the processing at the time of learning, in a case where a plurality of items of which a relationship is linear with each other are specified from data in a normal state, the abnormality detection apparatus reduces the amount of calculation by “randomly picking up some measurement values instead of using all the measurement values of the items”.

The processing at the time of learning by the abnormality detection apparatus will be described. The abnormality detection apparatus acquires data D in a normal state from an EV having a battery in a normal state. The data D in the normal state is defined by Equation (1). A measurement value dᵢ at a certain time included in the data D is defined by Equation (2).

The abnormality detection apparatus acquires data D′ in an abnormal state from an EV having a battery in an abnormal state. The data D′ in the abnormal state is defined by Equation (3). A measurement value d′ᵢ at a certain time included in data D′ is defined by Equation (4).

For example, a plurality of items included in the measurement value dᵢ represented by Equation (2) and the measurement value d′ᵢ represented by Equation (4) include items related to traveling of the EV such as a voltage, a current, an odometer, and the number of revolutions per minute of an engine.

The abnormality detection apparatus selects a plurality of items (1≤j₁, <, . . . <, jₘ≤m^{˜}) from all the items. The abnormality detection apparatus determines that the plurality of selected items have a linearity relationship with each other in a normal state and the original linearity of each other is largely collapsed in an abnormal state, by the following processing. The abnormality detection apparatus adopts the plurality of selected items as the “monitoring target items” when a condition described below is satisfied.

The abnormality detection apparatus executes first determination processing and second determination processing as described below. First, the “first determination processing” executed by the abnormality detection apparatus will be described. The abnormality detection apparatus creates a simple linear regression model for the measurement values (measurement values randomly picked up) of the plurality of selected items for the data D in the normal state. In the following description, the simple linear regression model is referred to as a “simple linear model”. The abnormality detection apparatus determines whether or not an error between the measurement values of the plurality of selected items and the simple linear model is small. The simple linear model corresponds to a “first linear model”.

The abnormality detection apparatus creates sub-data Dₘ obtained by narrowing down the items to j₁, . . . , jₘ from the data D. The items “j₁, . . . , jₘ” correspond to the plurality of selected items. The sub-data Dₘ is represented by Equation (5). A measurement value d_{m,i} at a certain time included in the sub-data Dₘ is defined by Equation (6).

The abnormality detection apparatus randomly selects “10×m+1” pieces of data “d_{m,i0}, . . . , d_{m,i10m}” from the sub-data Dₘ. m is the number of selected items. For example, in a case where two items of the voltage and the current are selected, m=2 is established. The abnormality detection apparatus calculates Euclidean distance from the origin for the data “d_{m,i0}, . . . , d_{m,i10m}” by using Equation (19), and replaces the data having the minimum value with “d_{m,i0}”.

$${d}_{m , {i}_{n}} = arg {min}_{{d}_{m , i} ∈ \{ {d}_{m , {i}_{0} , … , {d}_{m , {i}_{10 m}}} \}} {‖ {d}_{m , i} ‖}^{2} \qquad ( 19 )$$

The abnormality detection apparatus creates data D^{˜}ₘ based on “10×m+1” pieces of data “d_{m,i0}, . . . , d_{m,i10m}”. The data D^{˜}ₘ is represented by Equation (20). The measurement value at a certain time included in the data D^{˜}ₘ is defined by Equation (21). “d^{˜}ₘ” described in the specification corresponds to a symbol represented by “c” in Equation (20). As represented by Equation (21), “d_{m,i0}” is respectively subtracted from each data. This processing makes it possible to lower a dimension of the simple linear model by one.

$$\begin{matrix}\begin{matrix}{\tilde{D}}_{m} = \{ {\tilde{d}}_{m , {i}_{1} ,} {\tilde{d}}_{m , {i}_{2} ,} … , {\tilde{d}}_{m , {i}_{10 m}} \} \\ {↑}_{c}\end{matrix} & ( 20 ) \\ {\tilde{d}}_{m , i} = ( {\tilde{d}}_{i , {j}_{1}} , … , {\tilde{d}}_{i , {j}_{m}} ) = ( {d}_{i , {j}_{1}} - {d}_{m , {i}_{0}} , … , {d}_{i , {j}_{m}} - {d}_{m , {i}_{0}} ) & ( 21 )\end{matrix}$$

The abnormality detection apparatus creates a simple linear model by a least squares method by using each data of data D^{˜}ₘ for the measurement value of each item. The simple linear model is represented by Equation (22). β₁, . . . , βₘ₋₁ included in Equation (22) are coefficients of the simple linear model calculated by the least squares method. As represented by Equation (21), by processing of respectively subtracting “d_{m,i0}” from each data, it is possible to lower the dimension of the simple linear model by one, and therefore, β₀, which has been significant in Equation (7), is not significant.

y=f(x₁,x₂, . . . ,xₘ₋₁)=β₁x₁+ . . . +βₘ₋₁xₘ₋₁ (22)

A manager of the abnormality detection apparatus sets δ₁>0 as a threshold in advance. When the condition represented by Equation (23) is satisfied, the abnormality detection apparatus determines that the plurality of selected items have a linear relationship, and executes evaluation using data D′ in the abnormal state. In the following description, the plurality of selected items satisfying the condition represented by Equation (23) are referred to as “monitoring target candidate items”. In a case where the condition represented by Equation (23) is satisfied, it may be said that some measurement values of the monitoring target candidate items and the simple linear model have a predetermined correlation or more.

On the other hand, in a case where the condition represented by Equation (23) is not satisfied, the abnormality detection apparatus determines that there is no linearity relationship between the plurality of selected items, and ends the processing (selects a plurality of items of different combinations again, and determines whether the condition represented by Equation (23) is satisfied).

$$ɛ = {max}_{i = 1 , … , n} \vert {β}_{1} {\tilde{d}}_{i , {j}_{1}} + … + {β}_{m - 1} {\tilde{d}}_{i , {j}_{m - 1}} - {\tilde{d}}_{i , {j}_{m}} \vert < {δ}_{1} \qquad ( 23 )$$

Next, “second determination processing” executed by the abnormality detection apparatus will be described. In a case where the condition represented by Equation (23) is satisfied, the abnormality detection apparatus determines whether or not there is a large error between the measurement values of the monitoring target candidate items and the simple linear model for the data D′ in the abnormal state. The abnormality detection apparatus creates sub-data D′ₘ obtained by narrowing down the items to j₁, . . . , jₘ from the data D′. The items j₁, . . . , jₘ correspond to the monitoring target candidate items. The sub-data D′ₘ is represented by Equation (9). A measurement value d′_{m,i} at a certain time included in the sub-data D′ₘ is defined by Equation (10).

The abnormality detection apparatus creates data D′^{˜}ₘ based on the sub-data D′ₘ. The data D′^{˜}ₘ is represented by Equation (24). “D′^{˜}ₘ” described in the specification corresponds to a symbol represented by “d” in Equation (24). The measurement value d′^{˜}_{m,i} at a certain time included in the data D′^{˜}ₘ is defined by Equation (25). As represented by Equation (25), “d_{m,i0}” is respectively subtracted from each dimension, and the result may be applied to a regression equation of Equation (22). “d′^{˜}ₘ” described in the specification corresponds to a symbol represented by “e” in Equation (25).

$$\begin{matrix}{{\tilde{D}}_{m}^{′}}_{{↑}_{d}} = \{ {\tilde{d}}_{m , 1}^{′} , {\tilde{d}}_{m , 2}^{′} , … , {\tilde{d}}_{m , {n}^{′}}^{′} \} & ( 24 ) \\ {{\tilde{d}}_{m , i}^{′}}_{{↑}_{e}} = ( {\tilde{d}}_{i , {j}_{1}}^{′} , … , {\tilde{d}}_{i , {j}_{m}}^{′} ) = ( {d}_{i , {j}_{1}}^{′} - {d}_{m , {i}_{0}} , … , {d}_{i , {j}_{m}}^{′} - {d}_{m , {i}_{0}} ) & ( 25 )\end{matrix}$$

The abnormality detection apparatus sets δ₂>1 as a threshold in advance. The abnormality detection apparatus determines that the linearity of the monitoring target candidate items collapses when the condition represented by Equation (26) is satisfied, and adopts the monitoring target candidate items as the “monitoring target items”. “ε” included in Equation (26) corresponds to “ε” in Equation (23). On the other hand, when Equation (26) is not satisfied, the abnormality detection apparatus does not adopt the monitoring target candidate items as the monitoring target items.

$${max}_{i = 1 , … , {n}^{′}} \vert {β}_{1} {\tilde{d}}_{i , {j}_{1}}^{′} + … + {β}_{m - 1} {\tilde{d}}_{i , {j}_{m - 1}}^{′} - {\tilde{d}}_{i , {j}_{m}}^{′} \vert > {δ}_{2} ɛ \qquad ( 26 )$$

In a case where the abnormality detection apparatus creates a simple linear model by a least squares method, the coefficients β₁ to βₘ₋₁ of the simple linear model are calculated by solving the normal equation represented by Equation (14). In a case where the abnormality detection apparatus solves the normal equation of Equation (14), the data D^{˜}ₘ is as represented by Equation (20) and is m-dimensional. In a case where the coefficients of the simple linear model are calculated, since the abnormality detection apparatus calculates the coefficients by using only 10 m pieces of data of D^{˜}ₘ, without using all the measurement values of the items, it is possible to reduce an amount of calculation as compared with the reference apparatus.

After adopting the monitoring target items by using the simple linear model as described above, the abnormality detection apparatus may generate, for the monitoring target items, a linear regression model (that is not simple) that minimizes a square error with respect to all the measurement values of the monitoring target items in the normal state. The linear regression model that is not simple is represented by Equation (7).

Next, processing at the time of evaluation in which the abnormality detection apparatus detects an abnormality of the EV by using the monitoring target items will be described. The abnormality detection apparatus acquires data to be evaluated from the EV. Data d to be evaluated is represented by Equation (12).

The abnormality detection apparatus determines that the linearity largely collapses in a case where the data d to be evaluated satisfies the condition represented by Equation (27), and detects an abnormality. β₀, β¹, . . . , βₘ₋₁ in Equation (27) are coefficients of the linear regression model represented by Equation (7), which is calculated at the time of learning. δ₂ is a threshold set at the time of learning. “E” included in Equation (27) corresponds to “ε” in Equation (23). In a case where the abnormality detection apparatus does not create the linear regression model that is not simple, an abnormality may be detected by using a simple linear model.

|β₀+β₁dⱼ_{₁}+ . . . +βₘ₋₁dⱼ_{_{m−1}}−dⱼ_{ₘ}|>δ₂ε (27)

As described above, in the processing at the time of learning, in a case where the monitoring target items of which a relationship is linear with each other are specified from data in a normal state, the abnormality detection apparatus according to the present embodiment “randomly picks up some measurement values instead of using all the measurement values of the items”. Thus, the amount of calculation for calculating the monitoring target items may be reduced as compared with the reference technique.

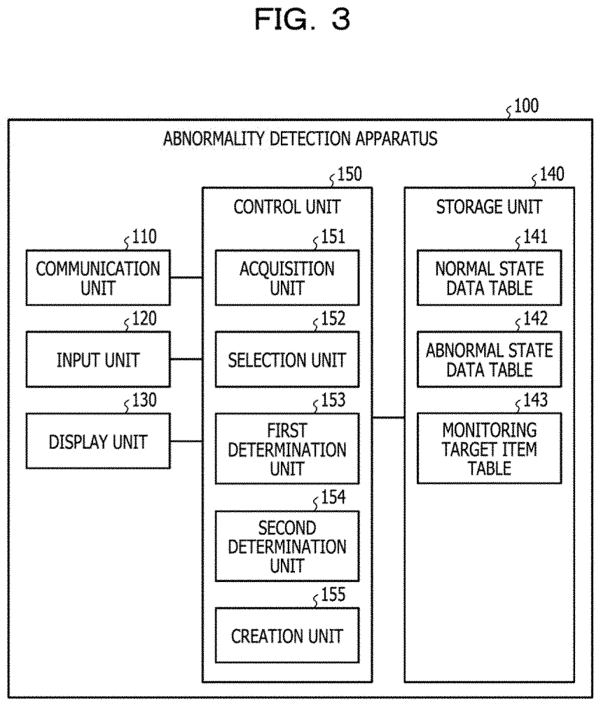

Next, an example of a configuration of the abnormality detection apparatus according to the present embodiment will be described. FIG. 3 is a functional block diagram illustrating a configuration of an abnormality detection apparatus according to the present embodiment. As illustrated in FIG. 3, the abnormality detection apparatus includes a communication unit 110, an input unit 120, a display unit 130, a storage unit 140, and a control unit 150.

The communication unit 110 is a device that receives data from an external device or the like via a network. The communication unit 110 is an example of a communication device. The control unit 150 described later may exchange data with the external device by using the communication unit 110. For example, the communication unit 110 receives data D in the normal state from the EV, from the external device or the like. The communication unit 110 receives data D′ in the abnormal state from the EV, from the external device or the like.

The input unit 120 is an input device for inputting various types of data to the control unit 150 of the abnormality detection apparatus 100. The input unit 120 corresponds to a keyboard, a mouse, a touch panel, and the like.

The display unit 130 is a display device that displays information output from the control unit 150. The display unit 130 corresponds to an organic electro luminescence (EL) display, a liquid crystal display, a touch panel, or the like.

The storage unit 140 has a normal state data table 141, an abnormal state data table 142, and a monitoring target item table 143. The storage unit 140 corresponds to a semiconductor memory element such as a random-access memory (RAM) and a flash memory, or a storage device such as a hard disk drive (HDD).

The normal state data table 141 is a table that holds data D in the normal state. The data D in the normal state is defined by Equation (1). A measurement value dᵢ at a certain time included in the data D is defined by Equation (2). n is the number of measurement values. m^{˜} is the number of items.

The abnormal state data table 142 is a table that holds data D′ in the abnormal state. The data D′ in the abnormal state is defined by Equation (3). A measurement value d′ᵢ at a certain time included in data D′ is defined by Equation (4). n′ is the number of measurement values. m^{˜} is the number of items.

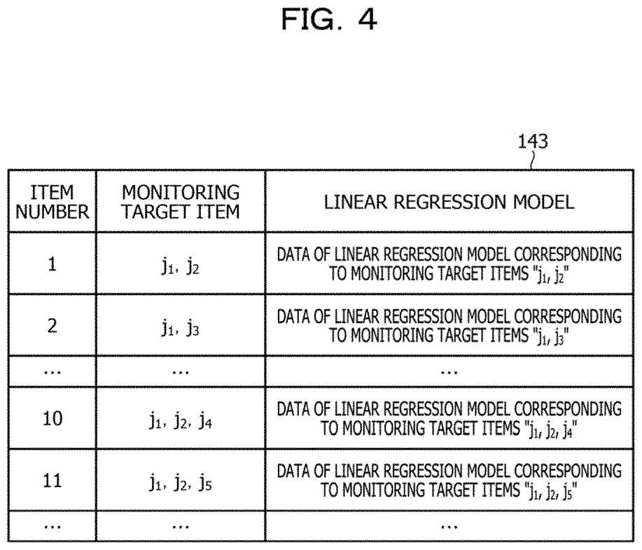

The monitoring target item table 143 is a table that holds data on the monitoring target items. FIG. 4 is a diagram illustrating an example of a data structure of a monitoring target item table. As illustrated in FIG. 4, the monitoring target item table 143 associates an item number, a monitoring target item, and a linear regression model with each other. The item number is a number for identifying each record in the monitoring target item table 143. The monitoring target items are a plurality of items in which the condition of Equation (23) is satisfied in the normal state and the condition of Equation (26) is satisfied in the abnormal state.

The linear regression model is parameter data of a linear regression model that minimizes a square error with respect to a measurement value of a monitoring target item in a normal state. The linear regression model is respectively created for each monitoring target item.

Description returns to FIG. 3. The control unit 150 includes an acquisition unit 151, a selection unit 152, a first determination unit 153, a second determination unit 154, and a creation unit 155. The control unit 150 may be implemented as a central processing unit (CPU), a microprocessor unit (MPU), or the like. The control unit 150 may also be implemented as a hard-wired logic circuit such as an application-specific integrated circuit (ASIC) and a field-programmable gate array (FPGA).

In a case where data D in the normal state is acquired from an EV having a battery in the normal state, the acquisition unit 151 stores the acquired data D in the normal state data table 141. In a case where a plurality of pieces of data D are acquired, the acquisition unit 151 may merge the data D.

In a case where data D′ in the abnormal state is acquired from an EV having a battery in the abnormal state, the acquisition unit 151 stores the acquired data D′ in the abnormal state data table 142. In a case where a plurality of pieces of data D′ are acquired, the acquisition unit 151 may merge the data D′.

The selection unit 152 selects a plurality of items from among the m^{˜} items, and outputs the plurality of selected items to the first determination unit 153. In a case where the information indicating that the condition of Equation (23) is satisfied is acquired from the first determination unit 153 for the plurality of selected items, the selection unit 152 specifies the plurality of selected items as the monitoring target candidate items. The selection unit 152 outputs the monitoring target candidate items to the second determination unit 154. In a case where the information indicating that the condition of Equation (26) is satisfied is acquired from the second determination unit 154 for the monitoring target candidate items, the selection unit 152 adopts the monitoring target candidate items as the monitoring target items and registers the monitoring target items in the monitoring target item table 143.

The selection unit 152 outputs the monitoring target items to the creation unit 155 to request the creation of the linear regression model corresponding to the monitoring target items. The linear regression model created by the creation unit 155 is registered in the monitoring target item table 143. The selection unit 152 may register a simple linear model in the monitoring target item table 143 instead of the linear regression model. The simple linear model is created by the first determination unit 153.

The selection unit 152 starts with the selection of two types of items from among the m^{˜} items, and selects three types of items when the selection of all of the two types of items is finished. The selection unit 152 repeatedly executes the above-described processing of selecting three types and four types of items until all of the m^{˜} types of items are selected.

The first determination unit 153 is a processing unit that executes the first determination processing described above for the item selected by the selection unit 152. The item selected by the selection unit 152 is referred to as a “selected item”. The first determination unit 153 acquires data D from the normal state data table 141 and creates a simple linear model by using a portion of the measurement values corresponding to the selected items. The processing of creating the simple linear model by the first determination unit 153 is the same as that described in the first determination processing described above.

When the condition represented by Equation (23) is satisfied, the first determination unit 153 determines that the selected items have a linearity relationship, and outputs the determination result to the selection unit 152. It is assumed that δ₁>0 is set as a threshold in advance.

The second determination unit 154 is a processing unit that executes the second determination processing described above when receiving the monitoring target candidate items from the selection unit 152. The second determination unit 154 acquires data D′ from the abnormal state data table 142 and determines whether the condition of Equation (26) is satisfied for the measurement values of the monitoring target candidate items. The second determination unit 154 acquires the value of ε and the value of the coefficient of the simple linear model from the first determination unit 153.

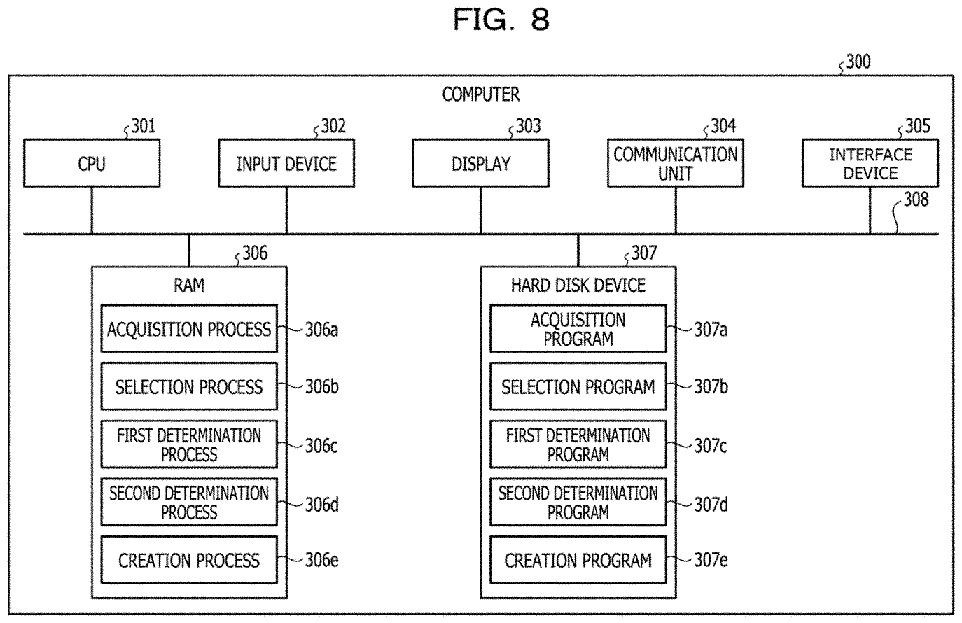

When the condition represented by Equation (26) is satisfied, the second determination unit 154 determines that the linearity of the monitoring target candidate items collapses, and outputs the determination result to the selection unit 152. It is assumed that δ₂>1 is set as a threshold in advance. The threshold δ₁ or the threshold 62 may be input by an operator from the input unit 120 or the input device 302 (FIG. 8).

The creation unit 155 is a processing unit that creates a linear regression model by using data D in the normal state in a case where the selected items are acquired from the acquisition unit 151. For example, in a case where the linear regression model is created by a least squares method, the creation unit 155 solves the normal equation represented by Equation (14). The creation unit 155 registers the linear regression model in the monitoring target item table 143. The linear regression model created by the creation unit 155 corresponds to a “second linear regression model”.

Next, processing at the time of evaluation for detecting an abnormality of the EV by using the monitoring target item table 143 will be described. A case where an evaluation device mounted on the EV executes the processing at the time of evaluation will be described, but the abnormality detection apparatus 100 may have a function of the evaluation device described below and detect an abnormality.

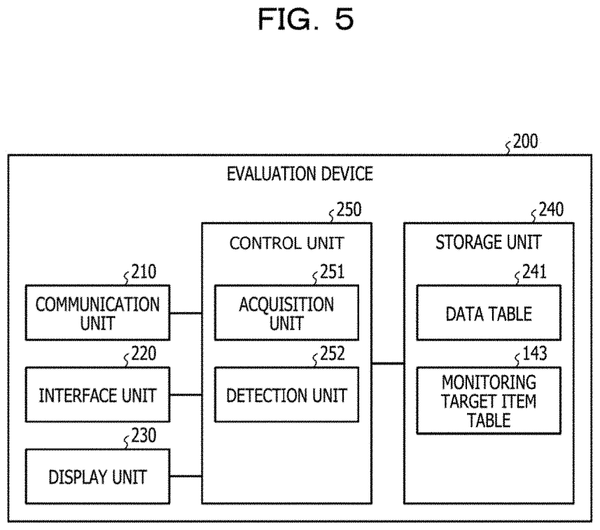

FIG. 5 is a functional block diagram illustrating a configuration of an evaluation device according to the present embodiment. As illustrated in FIG. 5, an evaluation device 200 has a communication unit 210, an interface unit 220, a display unit 230, a storage unit 240, and a control unit 250.

The communication unit 210 is a device that receives data from the abnormality detection apparatus 100, an external device, or the like via a network. The communication unit 210 is an example of the communication device. For example, the communication unit 210 receives data of the monitoring target item table 143 from the abnormality detection apparatus 100.

The interface unit 220 is a processing unit that receives an input of data to be evaluated from the control device related to traveling of the EV. The data to be evaluated is defined by Equation (12). The interface unit 220 outputs the data to be evaluated to the control unit 250.

The display unit 230 is a display device that displays information output from the control unit 250. The display unit 130 corresponds to an organic EL display, a liquid crystal display, a touch panel, or the like.

The storage unit 240 has a data table 241 and a monitoring target item table 143. The storage unit 240 corresponds to a semiconductor memory element, such as a RAM and a flash memory, or a storage device, such as an HDD.

The data table 241 is a table that holds data d to be evaluated.

The monitoring target item table 143 is a table that holds data on the monitoring target items. A description of the monitoring target item table 143 is the same as that described with reference to FIG. 4.

The control unit 250 has an acquisition unit 251 and a detection unit 252. The control unit 250 may be implemented by a CPU, an MPU, or the like. The control unit 250 may be implemented by a hard-wired logic circuit, such as an ASIC and an FPGA.

When acquiring data of the monitoring target item table 143 from the abnormality detection apparatus 100, the acquisition unit 251 registers the monitoring target item table 143 in the storage unit 240. When data to be evaluated is acquired via the interface unit 220, the acquisition unit 251 registers the data in the data table 241.

The detection unit 252 is a processing unit that detects an abnormality from the data to be evaluated stored in the data table 241. An example of the processing of the detection unit 252 will be described below. The detection unit 252 selects monitoring target items from the monitoring target item table 143 and acquires a linear regression model corresponding to the selected monitoring target items.

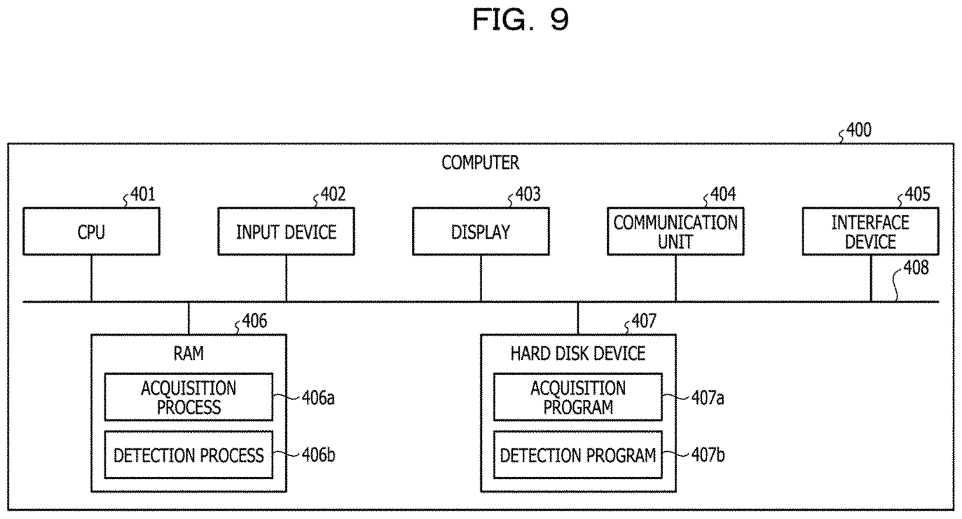

The detection unit 252 determines whether or not the measurement values of the monitoring target items among the items of the data d to be evaluated satisfy the condition represented by Equation (27). The detection unit 252 detects an abnormality in a case where the measurement values of the monitoring target items satisfy the condition represented by Equation (27). In a case where the condition represented by Equation (27) is satisfied, it means that the measurement values of the monitoring target items and the linear regression model do not have a predetermined correlation or more. In a case where an abnormality is detected, the detection unit 252 may cause the display unit 230 or the display 403 (FIG. 9) to display a warning screen prompting battery replacement.

When a plurality of monitoring target items are registered in the monitoring target item table 143, the detection unit 252 repeatedly executes the above-described processing for each monitoring target item. The manager may set a priority for each monitoring target item by referring to the monitoring target item table 143. When the priority is set for each monitoring target item, the detection unit 252 may execute the above-described processing for the monitoring target item having a higher priority.

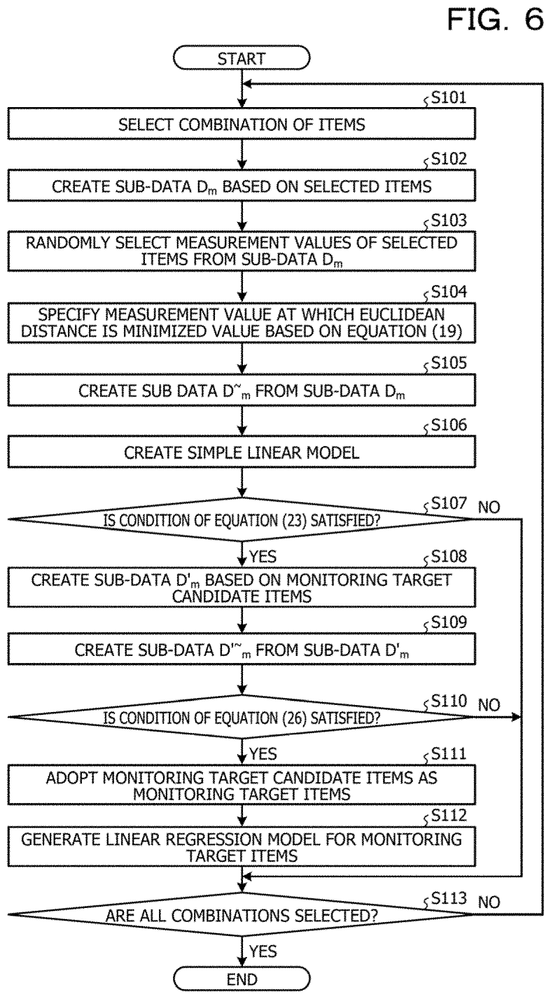

Next, an example of a processing procedure of the abnormality detection apparatus 100 will be described. FIG. 6 is a flowchart illustrating a processing procedure of the abnormality detection apparatus according to the present embodiment. As illustrated in FIG. 6, the selection unit 152 of the abnormality detection apparatus 100 selects a combination of items (step S101). The first determination unit 153 of the abnormality detection apparatus 100 creates sub-data Dₘ based on the selected items (Step S102).

The first determination unit 153 randomly selects measurement values of the selected items from the sub-data Dₘ (Step S103). The first determination unit 153 specifies a measurement value at which Euclidean distance is the minimum value, based on Equation (19) (Step S104).

The first determination unit 153 creates sub-data D^{˜}ₘ from the sub-data Dₘ (Step S105). The first determination unit 153 creates a simple linear model (Step S106).

When the condition of Equation (23) is not satisfied (No in step S107), the first determination unit 153 proceeds to step S113. On the other hand, in a case where the condition of Equation (23) is satisfied (Yes in step S107), the first determination unit 153 proceeds to step S108.

The second determination unit 154 creates sub-data D′ₘ based on the monitoring target candidate items (step S108). The second determination unit 154 creates sub-data D′^{˜}ₘ from the sub-data D′ₘ (step S109).

When the condition of Equation (26) is not satisfied (No in step S110), the second determination unit 154 proceeds to step S113. On the other hand, when the condition of Equation (26) is satisfied (Yes in step S110), the second determination unit 154 proceeds to step S111.

The selection unit 152 adopts the monitoring target candidate items as monitoring target items (step S111). The creation unit 155 of the abnormality detection apparatus 100 creates a linear regression model for the monitoring target items (step S112).

When all the combinations are not selected (No in step S113), the selection unit 152 proceeds to step S101. On the other hand, when all the combinations are selected (Yes in step S113), the selection unit 152 ends the processing.

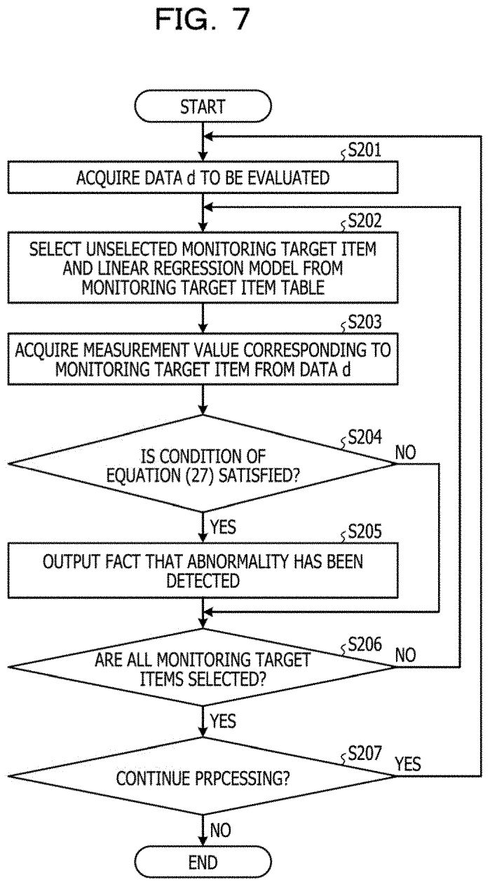

Next, an example of a processing procedure of the evaluation device 200 will be described. FIG. 7 is a flowchart illustrating the processing procedure of the evaluation device according to the present embodiment. As illustrated in FIG. 7, the acquisition unit 251 of the evaluation device 200 acquires data d to be evaluated (step S201).

The detection unit 252 of the evaluation device 200 selects an unselected monitoring target item and a linear regression model from the monitoring target item table 143 (step S202). The detection unit 252 acquires a measurement value corresponding to the monitoring target item from the data d (step S203).

When the condition of Equation (27) is not satisfied (No in step S204), the detection unit 252 proceeds to step S206. On the other hand, when the condition of Equation (27) is satisfied (Yes in step S204), the detection unit 252 outputs a fact that an abnormality has been detected (step S205).

When all the monitoring target items are not selected (No in step S206), the detection unit 252 proceeds to step S202. When all the monitoring target items are selected (Yes in step S206), the detection unit 252 proceeds to step S207.

In a case of continuing the processing (Yes in step S207), the evaluation device 200 proceeds to step S201. On the other hand, in a case of not continuing the processing (No in step S207), the evaluation device 200 ends the processing.

In the example illustrated in FIG. 7, the processing procedure in a case where the evaluation device 200 detects an abnormality from the data d to be evaluated has been described, but the present embodiment is not limited thereto. For example, the abnormality detection apparatus 100 may have the functions of the acquisition unit 251 and the detection unit 252. In this case, the abnormality detection apparatus 100 may execute processing of detecting an abnormality in accordance with the processing procedure described with reference to FIG. 7.

Next, effects of the abnormality detection apparatus 100 according to the present embodiment will be described. In the processing at the time of learning, the abnormality detection apparatus 100 randomly picks up some measurement values instead of using all the measurement values of the items from the data in the normal state and specifies the monitoring target candidate items of which the relationship is linear with each other. When the linearity of the measurement values of the monitoring target candidate items of the data in the abnormal state collapses, the abnormality detection apparatus 100 adopts the monitoring target candidate items as the monitoring target items. In this way, since the monitoring target candidate items of which the relationship is linear with each other are specified by randomly picking up some measurement values instead of using all the measurement values of the items from the data in the normal state, the amount of calculation may be reduced.

The abnormality detection apparatus 100 creates a simple linear model based on a least squares method by using a portion of the measurement values of the plurality of items, and determines that the relationship between the measurement values of the plurality of items has a linearity when the simple linear model and the portion of the measurement values do not deviate from each other (when there is a predetermined correlation or more). In this example, the target is an EV, and since there is a linear relationship between the items depending on the physical characteristic of the EV, it is possible to appropriately determine whether or not there is a linearity even in the simple linear model using a portion of measurement values.

The abnormality detection apparatus 100 specifies a minimum measurement value at which Euclidean distance from the origin is minimized among the portion of measurement values, and subtracts the minimum measurement value from each of the measurement values of the plurality of items, thereby lowering a dimension of a linear space of the sub-data D^{˜}ₘ. This may further reduce the amount of calculation.

Based on a linear regression model based on the measurement values of the monitoring target items, the abnormality detection apparatus 100 determines whether or not the newly acquired measurement values of the plurality of items have a predetermined correlation or more, and detects an abnormality when the measurement values do not have a predetermined correlation or more. In this way, an abnormality of a battery may be detected in advance.

When a plurality of monitoring target items are selected, the abnormality detection apparatus 100 determines, for each of the plurality of monitoring target items, whether the newly acquired measurement values of the plurality of items have a predetermined correlation or more. Therefore, in addition to a single monitoring target item, an abnormality of a battery may also be detected for other monitoring target items, and an accuracy of abnormality detection may be improved.

An example of an amount of calculation of the abnormality detection apparatus 100 will be described. In order to create a simple linear model, Euclidean distance calculation and model creation processing by a least squares method are executed. The amount of calculation in Euclidean distance calculation is o (10 m²). The amount of calculation in the model creation processing by a least squares method is o (10 m (m−1)²)+o (10 m (m−1))+o ((m−1)²).

Therefore, the amount of calculation for creating the simple linear model is o (10 m²)+o (10 m (m−1)²)+o (10 m (m−1))+o ((m−1)²).

In the reference apparatus described above, the amount of calculation for creating linear regression models for all combinations of items is defined by Equation (18). For example, the amount of calculation when m^{˜}=10, and n=10000 is 3.3×10⁷.

On the other hand, in the abnormality detection apparatus 100, the amount of calculation for creating linear regression models for all combinations of items is defined by Equation (28). For example, the amount of calculation when m^{˜}=10, and n=10000 is 1.6×10⁵. For example, the abnormality detection apparatus 100 may execute the calculation at a speed 197 times faster than that of the reference apparatus.

$${\sum }_{m = 2}^{\tilde{m}} ( \begin{matrix}\tilde{m} \\ \overline{m}\end{matrix} ) ( o ( 10 {m}^{2} ) + o ( 10 {m ( m - 1 )}^{2} ) + o ( 10 m ( m - 1 ) ) + o ( {( m - 1 )}^{2} ) ) \qquad ( 28 )$$

For example, according to the abnormality detection apparatus 100, by using a simple linear model with a small deviation from the linear regression model of the reference technique, it is possible to reduce the amount of calculation without deteriorating the detection accuracy. Thus, processing of selecting a monitoring target item may be executed at high speed.

Next, an example of a hardware configuration of a computer that implements functions similar to those of the abnormality detection apparatus 100 described in the above embodiment will be described. FIG. 8 is a diagram illustrating an example of a hardware configuration of a computer that implements functions similar to those of the abnormality detection apparatus according to the embodiment.

As illustrated in FIG. 8, a computer 300 has a CPU 301 that executes various types of arithmetic processing, an input device 302 that accepts input of data from a user, and a display 303. The computer 300 also has a communication device 304 that exchanges data with an external device or the like via a wired or wireless network, and an interface device 305 that is coupled to another device to exchange data. The computer 300 also has a RAM 306 that temporarily stores various types of information, and a hard disk device 307. Each of the devices 301 to 307 is coupled to a bus 308.

The hard disk device 307 has an acquisition program 307a, a selection program 307b, a first determination program 307c, a second determination program 307d, and a creation program 307e. The CPU 301 reads the programs 307a to 307e into the RAM 306.

The acquisition program 307a functions as an acquisition process 306a. The selection program 307b functions as a selection process 306b. The first determination program 307c functions as a first determination process 306c. The second determination program 307d functions as a second determination process 306d. The creation program 307e functions as a creation process 306e.

Processing of the acquisition process 306a corresponds to the processing of the acquisition unit 151. Processing of the selection process 306b corresponds to the processing of the selection unit 152. Processing of the first determination process 306c corresponds to the processing of the first determination unit 153. Processing of the second determination process 306d corresponds to the processing of the second determination unit 154. Processing of the creation process 306e corresponds to the processing of the creation unit 155.

The programs 307a to 307e may not be stored in the hard disk device 307 from the beginning. For example, the programs may be stored in a “portable physical medium”, such as a flexible disk (FD), a compact disc read-only memory (CD-ROM), a digital versatile disc (DVD), a magneto-optical disk, and an integrated circuit (IC) card, to be inserted into the computer 300. The computer 300 may read and execute the programs 307a to 307e.

The following describes an exemplary hardware configuration of a computer configured to implement functions similar to those of the evaluation device 200 described above in the embodiment. FIG. 9 is a diagram illustrating an exemplary hardware configuration of a computer that implements functions similar to those of the evaluation device according to the embodiment.

As illustrated in FIG. 9, a computer 400 has a CPU 401 that executes various types of arithmetic processing, an input device 402 that accepts input of data from a user, and a display 403. The computer 400 also has a communication device 404 that exchanges data with an external device or the like via a wired or wireless network, and an interface device 405 that is coupled to another device to exchange data. The computer 400 also has a RAM 406 that temporarily stores various types of information, and a hard disk device 407. Each of the devices 401 to 407 are coupled to a bus 408.

The hard disk device 407 has an acquisition program 407a and a detection program 407b. The CPU 401 reads the programs 407a and 407b into the RAM 406.

The acquisition program 407a functions as an acquisition process 406a. The detection program 407b functions as a detection process 406b.

Processing of the acquisition process 406a corresponds to the processing of the acquisition unit 251. Processing of the detection process 406b corresponds to the processing of the detection unit 252.

The programs 407a and 407b may not be stored in the hard disk device 407 from the beginning. For example, the programs may be stored in a “portable physical medium”, such as a flexible disk (FD), a CD-ROM, a DVD, a magneto-optical disk, and an IC card, to be inserted into the computer 400. The computer 400 may read and execute the programs 407a and 407b.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable recording medium having stored therein an abnormality detection program for causing a computer to execute a process comprising:
executing, for combinations of a plurality of items selected from measurement items related to a moving object, first determination of whether or not a relationship between measurement values of the plurality of items has a linearity by using a portion of the measurement values of the plurality of items;
executing, by using the measurement values of the plurality of items when an abnormality occurs, second determination of whether or not the relationship between the measurement values of the plurality of items when the abnormality occurs has the linearity; and
selecting the combinations of the plurality of items as monitoring target items for detecting an abnormality of the moving object when the relationship has the linearity in a normal state and the relationship does not have the linearity in an abnormal state.

2. The recording medium according to claim 1,
wherein the executing of the first determination includes determining that the relationship between the measurement values of the plurality of items has the linearity, when a first linear regression model based on a least squares method is created by using the portion of measurement values of the plurality of items, and the first linear regression model and the portion of measurement values have a predetermined correlation or more.

3. The recording medium according to claim 2, further causing the computer to execute a process comprising:
lowering the number of dimension of the first linear regression model by one by specifying a minimum measurement value at which Euclidean distance from an origin is minimized among the portion of measurement values, and subtracting the minimum measurement value from each of the measurement values of the plurality of items.

4. The recording medium according to claim 1, further causing the computer to execute a process comprising:
detecting an abnormality, by determining whether or not newly acquired measurement values of the plurality of items have a predetermined correlation or more based on a second linear regression model based on the measurement values of the monitoring target items, when the measurement values do not have the predetermined correlation or more.

5. The recording medium according to claim 4,
wherein the detecting of the abnormality includes determining, in a case where a plurality of the monitoring target items are selected, for each of the plurality of monitoring target items, whether or not the newly acquired measurement values of the plurality of items have a predetermined correlation or more.

6. An abnormality detection method performed by a computer, the method comprising:
executing, for combinations of a plurality of items selected from measurement items related to a moving object, first determination of whether or not a relationship between measurement values of the plurality of items has a linearity by using a portion of the measurement values of the plurality of items;
executing, by using the measurement values of the plurality of items when an abnormality occurs, second determination of whether or not the relationship between the measurement values of the plurality of items when the abnormality occurs has the linearity; and
selecting the combinations of the plurality of items as monitoring target items for detecting an abnormality of the moving object when the relationship has the linearity in a normal state and the relationship does not have the linearity in an abnormal state.

7. The abnormality detection method according to claim 6,
wherein the executing of the first determination includes determining that the relationship between the measurement values of the plurality of items has the linearity, when a first linear regression model based on a least squares method is created by using the portion of measurement values of the plurality of items, and the first linear regression model and the portion of measurement values have a predetermined correlation or more.

8. The abnormality detection method according to claim 7, the method further comprising:
lowering the number of dimension of the first linear regression model by one by specifying a minimum measurement value at which Euclidean distance from an origin is minimized among the portion of measurement values, and subtracting the minimum measurement value from each of the measurement values of the plurality of items.

9. The abnormality detection method according to claim 6, the method further comprising:
detecting an abnormality, by determining whether or not newly acquired measurement values of the plurality of items have a predetermined correlation or more based on a second linear regression model based on the measurement values of the monitoring target items, when the measurement values do not have the predetermined correlation or more.

10. The recording medium according to claim 9,
wherein the detecting of the abnormality includes determining, in a case where a plurality of the monitoring target items are selected, for each of the plurality of monitoring target items, whether or not the newly acquired measurement values of the plurality of items have a predetermined correlation or more.

11. An abnormality detection apparatus comprising:
a memory, and
a processor coupled to the memory and configured to:
execute, for combinations of a plurality of items selected from measurement items related to a moving object, first determination of whether or not a relationship between measurement values of the plurality of items has a linearity by using a portion of the measurement values of the plurality of items;
execute, by using the measurement values of the plurality of items when an abnormality occurs, second determination of whether or not the relationship between the measurement values of the plurality of items when the abnormality occurs has the linearity; and
select the combinations of the plurality of items as monitoring target items for detecting an abnormality of the moving object when the relationship has the linearity in a normal state and the relationship does not have the linearity in an abnormal state.

12. The abnormality detection apparatus according to claim 11,
Wherein in the execute the first determination, determine that the relationship between the measurement values of the plurality of items has the linearity, when a first linear regression model based on a least squares method is created by using the portion of measurement values of the plurality of items, and the first linear regression model and the portion of measurement values have a predetermined correlation or more.

13. The abnormality detection apparatus according to claim 12, the processor further configured to:
lower the number of dimension of the first linear regression model by one by specifying a minimum measurement value at which Euclidean distance from an origin is minimized among the portion of measurement values, and subtracting the minimum measurement value from each of the measurement values of the plurality of items.

14. The abnormality detection apparatus according to claim 11, the processor further configured to:
detect an abnormality, by determining whether or not newly acquired measurement values of the plurality of items have a predetermined correlation or more based on a second linear regression model based on the measurement values of the monitoring target items, when the measurement values do not have the predetermined correlation or more.

15. The abnormality detection apparatus according to claim 14,
wherein in the detect of the abnormality, determine, in a case where a plurality of the monitoring target items are selected, for each of the plurality of monitoring target items, whether or not the newly acquired measurement values of the plurality of items have a predetermined correlation or more.
